(19) United States
(12) Patent Application Publication
(10) Pub. No.: US 2026/0286202 A1
(43) Pub. Date: Sep. 24, 2026

(54) POLISHING COMPOSITION AND POLISHING METHOD

(71) Applicant: FUJIMI INCORPORATED, Kiyosu-shi (JP)

(72) Inventor: Ryota Mae, Kiyosu-shi (JP)

(73) Assignee: FUJIMI INCORPORATED, Kiyosu-shi (JP)

(21) Appl. No.: 19/548,243

(22) Filed: Feb. 24, 2026

(30) Foreign Application Priority Data
Mar. 19, 2025 (JP) 2025-044830

(51) Int. Cl. C09K 3/14

(52) U.S. Cl. CPC C09K 3/1463

(57) ABSTRACT

The present disclosure provides a polishing composition which allows the polishing removal rate of a material having a silicon-silicon bond to be enhanced and which is also excellent in step elimination ability on an object to be polished including the material having a silicon-silicon bond. The present disclosure relates to a polishing composition containing (A) a water-soluble polymer and (B) a polishing accelerator, wherein a content mass ratio of the (B) component to the (A) component ((B) component/(A) component) is more than 1, a dry film thickness measured by ellipsometry, of a coating film containing the (A) component and the (B) component, in which the coating film is formed after polishing of an object to be polished with the polishing composition containing the (A) component and the (B) component, is 20 Å or more, and an etching rate of the object to be polished, in the case of an etching test performed with the polishing composition containing the (A) component and the (B) component in Condition A, is 0.5 Å/min or more.

### TECHNICAL FIELD

The present disclosure relates to a polishing composition and a polishing method.

### BACKGROUND ART

In general, very fine patterning technologies are used for, for example, manufacturing of semiconductor devices, according to recent miniaturization and densification. Wires constituting semiconductor devices are, for example, multi-layered, thereby more complicating surface structures of semiconductor elements after stacking and also more increasing initial steps in surface films. Flatting technologies utilized for removal of initial steps in specified films formed on substrates are chemical mechanical polishing (CMP) processes. In a case where polishing objects to be polished by CMP have silicon-containing materials, polishing compositions for such silicon-containing materials are applied.

For example, International Publication No. WO2024/171892 discloses a polishing composition to be used for polishing a silicon wafer.

### SUMMARY

For example, when a film including a silicon-containing material having a specified initial step is polished to perform polishing of a height portion (thickness X (Å)) of the initial step at a polishing removal rate V (Å/min), the step is eliminated by polishing for X/V (min) as long as only an upper surface of a protruded portion of the step is selectively polished. However, in practice, a bottom of a depressed portion is also progressively polished at a lower rate than that of the upper portion of the protruded portion of the step, due to chemical etching in a CMP process, deflection of a polishing pad, or the like.

A polishing composition for a silicon-containing material is also demanded to have a step elimination efficiency closer to 1 (allowing only an upper portion of a protruded portion to be more selectively polished), as an excellent polishing composition. The step elimination efficiency is here determined as, in a certain polishing process, an amount (Å) of step height (in one depressed portion, a height (Å) from the lowest portion of a depressed portion to the uppermost portion of a protruded portion constituting the depressed portion) eliminated by polishing/a total amount of polishing in the polishing process (the distance (Å) from the height of the uppermost portion of the above protruded portion before polishing to the height of the uppermost portion of the above protruded portion after polishing.

Meanwhile, the polishing composition disclosed in International Publication No. WO2024/171892 is still insufficient in terms of polishing characteristics of an object to be polished including a silicon-containing material (for example, material having a silicon-silicon bond), in particular, performance about the step elimination efficiency, and there is room for improvement from this viewpoint. The polishing removal rate of a material having a silicon-silicon bond is also demanded to be enhanced.

An object of the present disclosure is then to provide a polishing composition which allows the polishing removal rate of a material having a silicon-silicon bond to be enhanced and which is also excellent in step elimination ability on an object to be polished including the material having a silicon-silicon bond.

The inventor of the present disclosure has made intensive studies in order to solve the above problems. As a result, the inventor has found that the above problems are solved by a polishing composition containing (A) a water-soluble polymer and (B) a polishing accelerator, in which the content mass ratio of the (B) component to the (A) component ((B) component/(A) component) is more than 1, the dry film thickness measured by ellipsometry, of a coating film containing the (A) component and the (B) component, in which the coating film is formed after polishing of an object to be polished with the polishing composition containing the (A) component and the (B) component, is 20 Å or more, and the etching rate of the polishing object, in the case of an etching test performed with the polishing composition containing the (A) component and the (B) component in Condition A, is 0.5 Å/min or more, thereby leading to completion of the invention of the present disclosure.

### DESCRIPTION OF EMBODIMENTS

The present disclosure relates to a polishing composition containing (A) a water-soluble polymer and (B) a polishing accelerator, wherein the content mass ratio of the (B) component to the (A) component ((B) component/(A) component) is more than 1, the dry film thickness measured by ellipsometry, of a coating film containing the (A) component and the (B) component, in which the coating film is formed after polishing of an object to be polished with the polishing composition containing the (A) component and the (B) component, is 20 Å or more, and the etching rate of the object to be polished, in the case of an etching test performed with the polishing composition containing the (A) component and the (B) component in Condition A, is 0.5 Å/min or more. The polishing composition according to the present disclosure, which has such a configuration, enhances the polishing removal rate of a material having a silicon-silicon bond and also is excellent in step elimination ability on an object to be polished including the material having a silicon-silicon bond.

Hereinafter, embodiments of the present disclosure are described. The present disclosure is not limited only to the following embodiments.

Herein, operations, and measurement of physical properties and the like are performed under conditions of room temperature (20° C. or more and 25° C. or less) and a relative humidity of 40% RH or more and 50% RH or less, unless particularly noted.

Herein, “X or more and Y or less” is used to mean that numerical values (X and Y) described before and after this range are included as the lower limit value and the upper limit value. In a case where a plurality of descriptions “X or more and Y or less” is made, for example, in a case where “X1 or more and Y1 or less, or X2 or more and Y2 or less” is described, all of the disclosure where each numerical value is adopted as the upper limit, the disclosure where each numerical value is adopted as the lower limit, and the disclosure of any combination of such upper limit and lower limit are made (namely, these serve as legitimate bases for amendments). Specifically, all of respective amendments to X1 or more, Y2 or less, X1 or less, Y2 or more, X1 or more and X2 or less, and X1 or more and Y2 or less need to be deemed to be legitimate.

It is to be understood that all combinations of embodiments and descriptions disclosed herein are disclosed in the present application. In other words, it is to be understood that these combinations can serve as bases for amendments.

### [(A) Water-Soluble Polymer]

The polishing composition according to the present disclosure includes a water-soluble polymer (hereinafter, also simply referred to as “(A) component”). The (A) component adsorbs to a surface of an object to be polished by hydrogen bonding or hydrophobic interaction, thereby forming a protective film. While this formation of the protective film occurs competitively with peeling of the protective film by polishing, the protective film is hardly peeled on a depressed portion as compared with a protruded portion and therefore it is considered that the polishing removal rate of the depressed portion is kept lower than the polishing removal rate of the protruded portion and the step elimination ability is enhanced. In other words, it is considered that the (A) component functions as an additive for step elimination.

The (A) component may be used singly or in combinations of two or more kinds thereof. The (A) component used here may be a synthetic product or a commercially available product.

The polishing composition according to the present disclosure includes a water-soluble polymer. The water-soluble polymer mentioned here refers to a water-soluble polymer having the same (homopolymer) or different (copolymer) repeating constituent unit, and can be typically a compound having a weight average molecular weight (Mw) of 1000 or more. The type of the polymer used as the water-soluble polymer is not particularly limited, and any of anionic, cationic, nonionic, and amphoteric polymers can be used. In a case where the water-soluble polymer is a copolymer, the form of the copolymer may be any of a block copolymer, a random copolymer, a graft copolymer, an alternate copolymer, and a periodic copolymer.

Examples of the anionic water-soluble polymer include polyvinylsulfonic acid, polystyrenesulfonic acid, polyallylsulfonic acid, polymethallylsulfonic acid, poly(2-acrylamide-2-methylpropanesulfonic acid), polyisoprenesulfonic acid, polyacrylic acid, polymethacrylic acid, and carboxymethylcellulose.

Examples of the cationic water-soluble polymer include polyethyleneimine (PEI), polyvinylamine, polyallylamine, polyvinylpyridine, and a polymer of cationic acrylamide. Specifically, for example, polydiallyldimethylammonium chloride or the like can be used.

Examples of the nonionic water-soluble polymer include polyvinyl alcohol, a water-soluble polymer having a lactam structure, such as polyvinylpyrrolidone, polyacrylamide, poly N-vinylacetamide, polyamines, polyvinyl ethers (polyvinyl methyl ether, polyvinyl ethyl ether, polyvinylisobutyl ether, and the like), polyalkylene oxides (polyethylene oxide, polypropylene oxide, and the like), polyglycerin, polyethylene glycol, polypropylene glycol, a polymer having a cellulose structure, such as hydroxymethylcellulose, hydroxyethylcellulose, and methylcellulose, alginic acid polyhydric alcohol ester, a water-soluble urea resin, a dextrin derivative, and casein. Not only one having such a main chain structure, but also a graft copolymer having a nonionic polymer structure at a side chain can also be suitably used.

Examples of the amphoteric water-soluble polymer include a copolymer of a vinyl monomer having an anionic group and a vinyl monomer having a cationic group, and a vinyl-based amphoteric polymer having a carboxybetaine group or a sulfobetaine group, and specifically include an acrylic acid/dimethylaminoethylmethacrylic acid copolymer and an acrylic acid/diethylaminoethylmethacrylic acid copolymer.

Furthermore, a copolymer of the water-soluble polymer exemplified above can also be used.

Among such water-soluble polymers, carboxymethylcellulose and a nonionic water-soluble polymer are preferred from the viewpoint of more easily adsorbing to an object to be polished. Furthermore, the nonionic water-soluble polymer is more preferably polyvinylpyrrolidone, hydroxymethylcellulose, hydroxyethylcellulose, or methylcellulose. In other words, according to one still further preferable embodiment of the present disclosure, the (A) component is at least one selected from the group consisting of polyvinylpyrrolidone, hydroxymethylcellulose, hydroxyethylcellulose, methylcellulose, and carboxymethylcellulose.

The lower limit of the weight average molecular weight (Mw) of the (A) component is preferably 1,000 or more, more preferably 3,000 or more, further preferably more than 5,000, particularly preferably 8,000 or more, most preferably 10,000 or more. The upper limit of the weight average molecular weight (Mw) of the (A) component is preferably 1,000,000 or less, more preferably 500,000 or less, further preferably 300,000 or less, particularly preferably 150,000 or less, most preferably less than 150,000. In other words, the weight average molecular weight (Mw) of the (A) component is preferably 1,000 or more and 1,000,000 or less, more preferably 3,000 or more and 500,000 or less, further preferably more than 5,000 and 300,000 or less, particularly preferably 8,000 or more and 150,000 or less, most preferably 10,000 or more and less than 150,000. The weight average molecular weight (Mw) of the (A) component can be measured as a value in terms of polyethylene glycol by use of gel permeation chromatography (GPC). The detail of the measurement method is described in Examples below.

The concentration (content) of the (A) component in the polishing composition is not particularly limited, and is preferably 0.0001% by mass or more, more preferably 0.0003% by mass or more, further preferably 0.0005% by mass or more, still further preferably 0.001% by mass or more, particularly preferably 0.005% by mass or more with respect to 100% by mass of the total mass of the polishing composition. The concentration (content) of the (A) component in the polishing composition is not particularly limited, and is preferably 0.3% by mass or less, more preferably 0.2% by mass or less, further preferably 0.1% by mass or less, still further preferably 0.08% by mass or less, particularly preferably 0.06% by mass or less with respect to 100% by mass of the total mass of the polishing composition.

In other words, the concentration (content) of the (A) component in the polishing composition is preferably 0.0001% by mass or more and 0.3% by mass or less, more preferably 0.0003% by mass or more and 0.2% by mass or less, further preferably 0.0005% by mass or more and 0.1% by mass or less, still further preferably 0.001% by mass or more and 0.08% by mass or less, particularly preferably 0.005% by mass or more and 0.06% by mass or less with respect to 100% by mass of the total mass of the polishing composition.

When the concentration (content) of the (A) component is in such a range, a polishing composition more excellent in step elimination ability can be obtained. In a case where the polishing composition includes two or more such (A) components, the concentration (content) of the (A) component means the total amount of such (A) components.

### [(B) Polishing Accelerator]

The polishing composition according to the present disclosure includes a (B) polishing accelerator (hereinafter, also simply referred to as “(B) component”). It is considered that the (B) component is added to embrittle a chemical bond (in particular, silicon-silicon bond) contained in an object to be polished and enhance the polishing removal rate of such an object to be polished (in particular, material containing a silicon-silicon bond).

The (B) component may be used singly or in combinations of two or more kinds thereof. The (B) component used here may be a synthetic product or a commercially available product.

The (B) component is not particularly limited, and is preferably an amine compound from the viewpoint that the ability to embrittle a silicon-silicon bond is high.

Examples of the amine compound include aliphatic amine, aliphatic heterocyclic (alicyclic) amine, aromatic amine, and aromatic heterocyclic amine.

Examples of the aliphatic amine include ethylamine, n-propylamine, isopropylamine, n-butylamine, isobutylamine, sec-butylamine, tert-butylamine, n-pentylamine, n-hexylamine, cyclohexylamine, ethylenediamine, dimethylamine, diethylamine, di(n-propyl)amine, diisopropylamine, di(n-butyl)amine, diisobutylamine, di(sec-butyl)amine, di(tert-butyl)amine, di(n-pentyl)amine, di(n-hexyl)amine, dicyclohexylamine, trimethylamine, triethylamine, diisopropylethylamine, N,N,N′,N′-tetramethyldiaminomethane, ethylenediamine, N,N′-dimethylethylenediamine, N,N′-diethylethylenediamine, N,N-dimethylethylenediamine, N,N-diethylethylenediamine, N,N,N′,N′-tetramethylethylenediamine, N,N,N′,N′-diethylethylenediamine, tetramethylenediamine, 1,2-propanediamine, 1,3-propanediamine, tetramethylenediamine, pentamethylenediamine, hexamethylenediamine, 1,7-diaminoheptane, 1,8-diaminooctane, 1,9-diaminononane, and 1,10-diaminodecane.

Examples of the aliphatic heterocyclic (alicyclic) amine include piperidine, pyrrolidine, N-methylpyrrolidine, piperazine, N-methylpiperazine, N,N′-dimethylpiperazine, 1-(2-aminoethyl)piperazine, 1-(2-dimethylaminoethyl)piperazine, 1,4-bis(3-aminopropyl)piperazine, N,N′,N″-trimethylaminoethylpiperazine, pyrrolidine, morpholine, methylmorpholine, ethylmorpholine, menthanediamine, isophoronediamine, N,N′,N″-tris(dimethylaminopropyl)hexahydro-s-triazine, a 3,9-bis(3-aminopropyl)-2,4,8,10-tetraoxyspiro(5,5)undecane adduct, bis(4-aminocyclohexyl)methane, 1,8-diazabicyclo-[5.4.0]-undec-7-ene (DBU), 1,5-diazabicyclo[4.3.0]non-5-ene (DBN), 1,4-diazabicyclo[2.2.2]octane (DABCO), and quinuclidine.

Examples of the aromatic amine include aniline, methylaniline, and N,N-dimethylaniline.

Examples of the aromatic heterocyclic amine include a pyrrole compound, an imidazole compound (imidazole, benzimidazole, and the like), a pyrazole compound, an oxazole compound, an isoxazole compound, a thiazole compound, an isothiazole compound, a melamine compound, a pyridine compound, a pyrimidine compound, a pyridazine compound, a pyrazine compound, a triazine compound, a quinoline compound, an isoquinoline compound, a quinazoline compound, a phthalazine compound, and an indole compound.

Among these amine compounds, an amine compound having 3 or more carbon atoms is preferred, and at least one selected from the group consisting of piperazine, 1-(2-aminoethyl)piperazine, 1,4-bis(3-aminopropyl)piperazine, and imidazole is more preferred. It is considered that such an amine compound can more promote embrittlement of a silicon-silicon bond contained in an object to be polished and more enhance the polishing removal rate of an object to be polished including a material containing a silicon-silicon bond.

The concentration (content) of the (B) component in the polishing composition is not particularly limited, and is preferably 0.005% by mass or more, more preferably 0.01% by mass or more, further preferably 0.04% by mass or more, particularly preferably 0.05% by mass or more with respect to 100% by mass of the total mass of the polishing composition. The concentration (content) of the (B) component in the polishing composition is not particularly limited, and is preferably 3% by mass or less, more preferably 2% by mass or less, further preferably 1% by mass or less, particularly preferably 0.6% by mass or less with respect to 100% by mass of the total mass of the polishing composition.

In other words, the concentration (content) of the (B) component in the polishing composition is preferably 0.005% by mass or more and 3% by mass or less, more preferably 0.01% by mass or more and 2% by mass or less, further preferably 0.04% by mass or more and 1% by mass or less, particularly preferably 0.05% by mass or more and 0.6% by mass or less with respect to 100% by mass of the total mass of the polishing composition.

When the concentration (content) of the (B) component is in this range, a polishing composition which is more excellent in step elimination ability and which can enhance the polishing removal rate of a material having a silicon-silicon bond. In a case where the polishing composition includes two or more such (B) components, the concentration (content) of the (B) component means the total amount of such components.

### [Content Mass Ratio of (B) Component to (A) Component ((B) Component/(A) Component)]

The content mass ratio of the (B) component to the (A) component ((B) component/(A) component) in the polishing composition according to the present disclosure is more than 1. In a case where the content mass ratio is 1 or less, the step elimination ability, and the polishing removal rate of a material having a silicon-silicon bond are lowered. The content mass ratio of the (B) component to the (A) component ((B) component/(A) component) in the polishing composition is preferably 2 or more, more preferably 5 or more, further preferably 7 or more, still further 10 or more, particularly preferably more than 10. The content mass ratio of the (B) component to the (A) component ((B) component/(A) component) is preferably 200 or less, more preferably 150 or less, further preferably 100 or less, further preferably 70 or less, particularly preferably 50 or less.

In other words, the content mass ratio of the (B) component to the (A) component ((B) component/(A) component) in the polishing composition is preferably 2 or more and 200 or less, more preferably 5 or more and 150 or less, further preferably 7 or more and 100 or less, still further preferably 10 or more and 70 or less, particularly preferably more than 10 and 50 or less.

In a case where the polishing composition includes two or more such (A) components, the content of the (A) component means the total amount of such components. Similarly, in a case where the polishing composition includes two or more such (B) components, the content of the (B) component means the total amount of such components.

### [Film Thickness of Coating Film]

The dry film thickness measured by ellipsometry (hereinafter, also simply referred to as “dry film thickness”), of a coating film containing the (A) component and the (B) component, in which the coating film is formed after polishing of an object to be polished with the polishing composition according to the present disclosure including the (A) component and the (B) component, is 20 Å or more. In a case where the dry film thickness is less than 20 Å, step elimination ability is lowered.

The dry film thickness is preferably 21 Å or more, and can be 22 Å or more, 23 Å or more, 24 Å or more, 25 Å or more, or 26 Å or more. The upper limit of the dry film thickness is not particularly limited, and is usually 200 Å or less and can be 100 Å or less, 50 Å or less, 40 Å or less, or 30 Å or less. Herein, 1 Å=0.1 nm is satisfied.

In the present disclosure, the dry film thickness adopted here is a value determined by measuring the film thickness of a coating film on an object to be polished after polishing and furthermore drying of the object to be polished, by spectroscopic ellipsometry. The detail of the measurement method is as described in Examples.

The dry film thickness can be controlled by appropriately selecting the type, the weight average molecular weight (Mw) and the concentration of the (A) component, the type and the concentration of the (B) component, the polishing pressure, and the like.

### [Etching Rate]

The etching rate of an object to be polished in the case of polishing performed with the polishing composition containing the (A) component and the (B) component in Condition A (hereinafter, also simply referred to as “etching rate”) is 0.5 Å/min or more. In a case where the etching rate is less than 0.5 Å/min, the polishing removal rate of the polishing object is lowered.

Here, Condition A of the etching test in which the etching rate is measured is the following condition.

### <Condition A>

A test piece used here is a silicon wafer (200 mm, blanket wafer) on which an amorphous silicon film having a thickness of 2000 Å is formed on a surface of the wafer. This wafer is cut to a size of 60 mm×60 mm to provide a coupon wafer, and the coupon wafer is dipped in 500 ml of the polishing composition being stirred, in the following conditions:
Dipping time: 120 minutes
Dipping temperature: 40° C.
Rotational speed of stirrer: 300 rpm.

The etching rate can be calculated by determining the thicknesses of the amorphous silicon film before and after dipping with an optical film thickness measurement instrument, and dividing [(Thickness before dipping)−(Thickness after dipping)] by the dipping time.

Such Condition A replicates etching of amorphous silicon in an actual polishing environment, and is well consistent with polishing results.

The etching rate is preferably 0.8 Å/min or more, and can be 0.9 Å/min or more, 1.0 Å/min or more, 1.1 Å/min or more, 1.5 Å/min or more, 1.7 Å/min or more, or 2.0 Å/min or more. The upper limit of the etching rate is not particularly limited, and is usually 100 Å/min or less, and can be 50 Å/min or less, 10 Å/min or less, 5 Å/min or less, or 3 Å/min or less.

The etching rate can be controlled by appropriately selecting the type, the weight average molecular weight (Mw) and the concentration of the (A) component, the type and the concentration of the (B) component, and the like.

### [Electrical Conductivity of Polishing Composition]

The electrical conductivity (EC) of the polishing composition according to the present disclosure is not particularly limited, and is preferably 0.5 mS/cm or more and 20 mS/cm or less, more preferably 0.8 mS/cm or more and 15 mS/cm or less, further preferably 1 mS/cm or more and 10 mS/cm or less.

The electrical conductivity of the polishing composition can be adjusted depending on the type and the concentration of the (B) component, and the type, the concentration, and the like of a pH adjusting agent described later. The electrical conductivity of the polishing composition can be measured by a method described in Examples.

The polishing composition according to the present disclosure may further include an electrical conductivity adjusting agent for adjusting the electrical conductivity. The electrical conductivity adjusting agent is not particularly limited as long as it is any other component than the (B) component and the pH adjusting agent and has a function of adjusting the electrical conductivity, and examples thereof include a salt compound.

### [Abrasive Grain]

The polishing composition according to the present disclosure may include an abrasive grain.

The abrasive grain is not particularly limited, and may be any of an inorganic particle and an organic particle. The inorganic particle is not particularly limited, and examples include particle including a metal oxide such as silica, alumina, ceria, or titania. The organic particle is not particularly limited, and examples include a polymethyl methacrylate (PMMA) particle. In particular, the abrasive grain is preferably silica (silica abrasive grain), or colloidal silica (colloidal silica abrasive grain).

The shape of the abrasive grain is not particularly limited, and may be a spherical shape or a non-spherical shape. Specific examples of the non-spherical shape include various shapes, for example, polygonal columns such as a triangular column and a quadrangular column, a cylindrical shape, a bale shape in which the central portion of a cylinder is bulged as compared with an end portion, a donut shape in which the central portion of a disc penetrates, a plate-like shape, a so-called cocoon-like shape having a constriction at the central portion, a so-called associated spherical shape in which plural particles are integrated, a beaded shape in which plural particles are joined substantially in line, a so-called “konpeito” shape having plural protrusions on the surface, a rugby ball shape, and a needle-like shape finer than a rugby ball shape, but are not particularly limited thereto. In particular, a cocoon-like shape is preferred.

The average primary particle size of the abrasive grain is not particularly limited, and is preferably 5 nm or more, more preferably 7 nm or more, further preferably 10 nm or more, still further preferably 25 nm or more, particularly preferably 30 nm or more. In a case where the average primary particle size is in this range, the polishing removal rate is more enhanced. The average primary particle size of the abrasive grain is not particularly limited, and is preferably 120 nm or less, more preferably 80 nm or less, further preferably 50 nm or less, particularly preferably 40 nm or less. The average primary particle size of the abrasive grain can be calculated from the specific surface area of the abrasive grain, determined by a BET method.

The average secondary particle size of the abrasive grain is not particularly limited, and is preferably 10 nm or more, more preferably 20 nm or more, further preferably 30 nm or more, particularly preferably 50 nm or more. The average secondary particle size of the abrasive grain is not particularly limited, and is preferably 250 nm or less, more preferably 200 nm or less, further preferably 150 nm or less, particularly preferably 100 nm or less. The value of the average secondary particle size of the abrasive grain can be measured by a dynamic light scattering method.

The abrasive grain may be used singly or in combinations of two or more kinds thereof. The abrasive grain used here may be a synthetic product or a commercially available product.

However, the concentration (content) of the abrasive grain is preferably 0.5% by mass or less based on the total mass of the polishing composition from the viewpoint that the polishing removal rate of a material containing a silicon-nitrogen bond, used as a stop film, is suppressed as much as possible. The concentration (content) of the abrasive grain is more preferably less than 0.5% by mass, further preferably 0.3% by mass or less, particularly preferably 0.1% by mass or less. The most preferred mode is a mode in which the concentration (content) of the abrasive grain is 0% by mass, namely, the abrasive grain is not included in the polishing composition at all. Here, in a case where the abrasive grain is included in the polishing composition, the lower limit value of the concentration (content) of the abrasive grain is more than 0% by mass.

### [pH and pH Adjusting Agent]

The pH of the polishing composition according to the present disclosure is not particularly limited, and is preferably 8 or more and 12 or less. The pH is more preferably 8.5 or more, further preferably 9 or more. The upper limit of the pH is more preferably 12 or less, further preferably 11.5 or less, further preferably 11 or less. In other words, the pH of the polishing composition according to the present disclosure is preferably 8 or more and 12 or less, more preferably 8.5 or more and 11.5 or less, further preferably 9 or more and 11 or less.

The (A) component and the (B) component in the present disclosure can serve as a pH adjusting agent. Here, if the above desired pH is not obtained by only the (A) component and the (B) component, the polishing composition according to the present disclosure may further include a pH adjusting agent other than the (A) component and the (B) component. This pH adjusting agent is not particularly limited, a known pH adjusting agent can be used, or a known acid, base, or any salt thereof can be used. Examples of this pH adjusting agent include organic acids, for example, carboxylic acids such as formic acid, acetic acid, glycolic acid, propionic acid, butyric acid, valeric acid, caproic acid, enanthic acid, caprylic acid, pelargonic acid, capric acid, lauric acid, myristic acid, palmitic acid, margaric acid, stearic acid, oleic acid, linoleic acid, linolenic acid, arachidonic acid, docosahexaenoic acid, eicosapentaenoic acid, lactic acid, malic acid, tartaric acid, citric acid, benzoic acid, phthalic acid, isophthalic acid, terephthalic acid, salicylic acid, gallic acid, mellitic acid, cinnamic acid, oxalic acid, malonic acid, succinic acid, glutaric acid, adipic acid, fumaric acid, maleic acid, aconitic acid, amino acids and anthranilic acid, sulfonic acids (isethionic acid, camphorsulfonic acid, and the like), and organic phosphonic acids (hydroxyethylidene diphosphonic acid, and diethylenetriamine pentamethylene phosphonic acid, and the like); inorganic acids such as nitric acid, carbonic acid, hydrochloric acid, sulfuric acid, phosphoric acid, hypophosphorous acid, phosphorus acid, phosphonic acid, boric acid, hydrofluoric acid, orthophosphoric acid, pyrophosphoric acid, metaphosphoric acid, and hexametaphosphoric acid; hydroxides of alkali metals, such as potassium hydroxide (KOH) and sodium hydroxide (NaOH); carbonates of alkali metals, such as potassium carbonate (K₂CO₃) and sodium carbonate (Na₂CO₃); hydroxides of alkalin earth metals; ammonia (ammonium hydroxide); and organic bases such as a quaternary ammonium hydroxide compound.

Such a pH adjusting agent may be used singly or in combinations of two or more kinds thereof. Such a pH adjusting agent used here may be a synthetic product or a commercially available product.

The pH of the polishing composition can be measured with, for example, a pH meter, and specifically can be measured by a method described in Examples.

### [Dispersing Medium]

The polishing composition according to the present disclosure preferably includes a dispersing medium for dispersing each component. Examples of the dispersing medium can include water; alcohols such as methanol, ethanol, and ethylene glycol; ketones such as acetone, and any mixture thereof. In particular, the dispersing medium is preferably water. In other words, according to a preferred mode of the present disclosure, the dispersing medium includes water. According to a more preferred mode of the present disclosure, the dispersing medium substantially includes water. Herein, the “substantially” means that any other dispersing medium than water can be included as long as the effects of the present disclosure are achieved. More specifically, the dispersing medium preferably includes 90% by mass or more and 100% by mass or less of water and 0% by mass or more and 10% by mass or less of any other dispersing medium than water, more preferably includes 99% by mass or more and 100% by mass or less of water and 0% by mass or more and 1% by mass or less of any other dispersing medium than water. The dispersing medium is most preferably water.

The dispersing medium is preferably water not containing impurities as much as possible from the viewpoint of not inhibiting the effects of the components included in the polishing composition. Specifically, the dispersing medium is more preferably ion exchange water (deionized water), pure water or ultrapure water obtained by removing impurity ions with an ion exchange resin and then removing foreign substances through a filter, or distilled water.

### [Other Components]

The polishing composition according to the present disclosure may further contain any known additive usable for polishing compositions, such as a complexing agent, an antiseptic agent, a surfactant, an antifungal agent, and/or an oxidizing agent as long as the effects of the present disclosure are not impaired. According to one embodiment of the present disclosure, the polishing composition may further contain an antifungal agent. In other words, in one embodiment of the present disclosure, the polishing composition is substantially constituted from (A) the water-soluble polymer, (B) the polishing accelerator, the dispersing medium, and at least one of the pH adjusting agent and an antifungal agent. In one embodiment of the present disclosure, the polishing composition is substantially constituted from (A) the water-soluble polymer, (B) the polishing accelerator, the dispersing medium, and the pH adjusting agent. Herein, the “polishing composition is substantially constituted from (A) the water-soluble polymer, (B) the polishing accelerator, the dispersing medium, and at least one of the pH adjusting agent and an antifungal agent” means that the total content of (A) the water-soluble polymer, (B) the polishing accelerator, the dispersing medium, the pH adjusting agent, and the antifungal agent is more than 99% by mass (upper limit: 100% by mass) based on the total mass of the polishing composition. The polishing composition is preferably constituted from (A) the water-soluble polymer, (B) the polishing accelerator, the dispersing medium, and the pH adjusting agent (the total content=100% by mass).

Examples of the antifungal agent (antiseptic agent) which can be added to the polishing composition according to the present disclosure include 1,2-benzoisothiazol-3 (2H)-one (BIT); isothiazoline-based antiseptic agents such as 2-methyl-4-isothiazolin-3-one and 5-chloro-2-methyl-4-isothiazolin-3-one; paraoxybenzoates; and phenoxyethanol. Such an antifungal agent may be used singly or in combinations of two or more kinds thereof.

### [Method for Producing Polishing Composition]

The method for producing the polishing composition according to the present disclosure is not particularly limited, and the polishing composition can be obtained by, for example, stirring and mixing the (A) component, the (B) component, and, if necessary, any other additive in the dispersing medium (for example, water). The detail of each of the components is as described above.

The temperature during mixing of each of the components is not particularly limited, and is preferably 10° C. or more and 40° C. or less, and heating may also be performed for increasing the rate of dissolution. The mixing time is also not particularly limited as long as uniform mixing can be made.

### [Object to be Polished]

A polishing composition according to one embodiment of the present disclosure can be applied to a known object to be polished which is not particularly limited and which is used in the CMP field. Therefore, an aspect of the object to be polished is not particularly limited, a layer being a flat-plate-like member is preferred, a substrate including the layer is more preferred, and a semiconductor substrate is further preferred. Examples include a substrate constituted from a single layer, and a substrate including a layer to be polished and any other layer (for example, a support layer or any other functional layer). Examples of the material constituting the object to be polished include, but not particularly limited thereto, a silicon-containing material and a metal-containing material (for example, a metal simple substance, metal oxide, and metal nitride). The material constituting the object to be polished may be adopted singly or in combinations of two or more kinds thereof.

Examples of the silicon-containing material include, but not particularly limited thereto, a material having a silicon-oxygen bond, a material having a silicon-silicon bond, and a material having a silicon-nitrogen bond. Examples of the material having a silicon-oxygen bond include, but not particularly limited thereto, silicon oxide, BD (black diamond: SiOCH), FSG (fluorosilicate glass), HSQ (hydrogen silsesquioxane), CYCLOTENE, SiLK, and MSQ (Methyl silsesquioxane). Examples of the object to be polished having a silicon-silicon bond include, but not particularly limited thereto, polycrystalline silicon (polysilicon, Poly-Si), amorphous silicon (a-Si), monocrystalline silicon, n-type doped monocrystalline silicon, and p-type doped monocrystalline silicon, and Si-type alloys such as SiGe. Examples of the material having a silicon-nitrogen bond include, but not particularly limited thereto, silicon nitride and silicon carbonitride (SiCN).

Among such silicon-containing materials, the material having a silicon-silicon bond is preferred, and amorphous silicon is more preferred. The object to be polished preferably includes not only the material having a silicon-silicon bond, but also the material having a silicon-nitrogen bond. A film including the material having a silicon-nitrogen bond can be used as a stop film.

### [Polishing Method]

As described above, the polishing composition according to the present disclosure is suitably used for polishing an object to be polished containing a material having a silicon-silicon bond. Accordingly, the present disclosure provides a polishing method including a step of polishing an object to be polished containing a material having a silicon-silicon bond with the polishing composition according to the present disclosure. The present disclosure provides a method for producing a substrate, the method including polishing an object to be polished containing a material having a silicon-silicon bond by the polishing method according to the present disclosure.

The polishing apparatus used here can be a common polishing apparatus which is equipped with a holder for retaining a substrate or the like having an object to be polished and a motor changeable in number of rotations, and the like, and which has a polishing table to which a polishing pad (polishing cloth) can be attached.

The type of the polishing pad used in the polishing method and the method for producing a semiconductor substrate, according to the present disclosure, is not particularly limited, and, for example, an expanded polyurethane type, a non-woven cloth type, or a suede type can be used.

The shore D hardness of the polishing pad is preferably 30 or more. When the shore D hardness is 30 or more, the pressure applicable to an object to be polished can be increased and the polishing removal rate is more enhanced. The shore D hardness of the polishing pad is more preferably 40 or more, further preferably 50 or more. The shore D hardness of the polishing pad is preferably 90 or less, more preferably 80 or less, further preferably 70 or less. When the shore D hardness is 90 or less, the polishing pad can well follow an object to be polished surface during polishing and polishing can be stably performed. The shore D hardness can be measured by a method described in JIS K 7215:1986.

Among polishing conditions, for example, the rotational speed of a polishing table is, for example, preferably 10 rpm (0.17 s⁻¹) or more and 500 rpm (8.33 s⁻¹). The pressure (polishing pressure) applied to a substrate having an object to be polished is preferably 0.5 psi (3.4 kPa) or more and 10 psi (68.9 kPa). The method for supplying the polishing composition to the polishing pad is also not particularly limited, and, for example, a continuously supplying method with a pump or the like is adopted. The amount of this supplying is not limited, and a surface of the polishing pad is preferably always covered with the polishing composition according to the present disclosure.

After completion of polishing, a substrate is washed in flowing water and water droplets attached onto the substrate are blown away with a spin dryer or the like, thereby providing a substrate containing a material having a silicon-silicon bond.

The polishing composition according to the present disclosure may be of one-liquid-type, or of multi-liquid type including two-liquid type. The polishing composition according to the present disclosure may also be prepared by diluting a stock solution of the polishing composition with a dilution liquid such as water to, for example, 2 times or more and 10 times or less.

A polishing composition according to more preferred one aspect of the present disclosure is suitably used for polishing an object to be polished having a material having a silicon-silicon bond, in which the material is embedded on a substrate having a depressed portion so as to cover the depressed portion. In other words, the present disclosure provides a polishing method including polishing a material having a silicon-silicon bond, in which the material is embedded on a substrate having a depressed portion so as to cover the above depressed portion, with the polishing composition of the present disclosure.

Specific examples of the material having a silicon-silicon bond, in which the material is embedded on a substrate having a depressed portion so as to cover the depressed portion, include the above material having a silicon-silicon bond, more preferably include amorphous silicon. Here, a stop film may be formed between a film including the material having a silicon-silicon bond and the substrate. Examples of the material of such a stop film include a material having a silicon-nitrogen bond, preferably include silicon nitride.

### [Step Elimination Ability]

A polishing method with a polishing composition according to preferred one embodiment of the present disclosure includes polishing a surface of an object to be polished containing a material having a silicon-silicon bond, with the polishing composition. Thus, polishing characteristics of the polishing object can be more enhanced. In particular, in a case where a step due to multi-layering of wires, or the like, for example, an initial step is generated on a surface of a substrate, the step elimination ability can be enhanced. This step elimination ability can be evaluated with the step elimination efficiency determined as, in a certain polishing process, an amount (Å) of step height (in one depressed portion, a height (Å) from the lowest portion of a depressed portion to the uppermost portion of a protruded portion constituting the depressed portion) eliminated by polishing (the amount of step elimination)/a total amount of polishing in the polishing process (the distance (Å) from the height of the uppermost portion of the above protruded portion before polishing to the height of the uppermost portion of the above protruded portion after polishing. As such a value is closer to 1, only an upper surface of the protruded portion can be selectively polished to make the polishing efficiency more excellent. The step elimination efficiency is preferably 0.15 (15%) or more, more preferably 0.2 (20%) or more, further preferably 0.25 (25%) or more, particularly preferably 0.3 (30%) or more in the case of polishing in polishing conditions of, for example, a polishing pressure of 2.5 psi (17.2 kPa) and a number of polishing table rotations of 90 rpm (1.5 s⁻¹).

### [Polishing Removal Rate]

The polishing composition according to the present disclosure can enhance the polishing removal rate of particularly an object to be polished containing a material having a silicon-silicon bond.

In a case where polishing is performed with the polishing composition according to the present disclosure, the polishing removal rate of the material having a silicon-silicon bond may be preferably 1500 Å/min or more, 1600 Å/min or more, 1700 Å/min or more, 1800 Å/min or more, 1900 Å/min or more, or 2000 Å/min or more.

Although embodiments of the present disclosure are described in detail, it is clear that these embodiments are descriptive and illustrative and are not limiting and the scope of the present disclosure is to be interpreted by the accompanying claims.

The present disclosure encompasses the following aspects and modes:
[1] A polishing composition containing
(A) a water-soluble polymer, and
(B) a polishing accelerator, wherein
a content mass ratio of the (B) component to the (A) component ((B) component/(A) component) is more than 1,
a dry film thickness measured by ellipsometry, of a coating film containing the (A) component and the (B) component, in which the coating film is formed after polishing of an object to be polished with the polishing composition containing the (A) component and the (B) component, is 20 Å or more, and
an etching rate of the object to be polished, in the case of an etching test performed with the polishing composition containing the (A) component and the (B) component in Condition A, is 0.5 Å/min or more:
[2] The polishing composition according to [1], wherein the (A) component is at least one selected from the group consisting of polyvinylpyrrolidone, hydroxymethylcellulose, hydroxyethylcellulose, methylcellulose, and carboxymethylcellulose:
[3] The polishing composition according to [1] or [2], wherein the (B) component is an amine compound having 3 or more carbon atoms:
[4] The polishing composition according to [3], wherein the (B) component is at least one selected from the group consisting of piperazine, 1-(2-aminoethyl)piperazine, 1,4-bis(3-aminopropyl)piperazine, and imidazole:
[5] The polishing composition according to any of [1] to [4], wherein the content mass ratio of the (B) component to the (A) component ((B) component/(A) component) is more than 10 and 50 or less:
[6] The polishing composition according to any of [1] to [5], further containing a dispersing medium:
[7] The polishing composition according to any of [1] to [6], wherein a pH is 8 or more and 12 or less:
[8] The polishing composition according to any of [1] to [7], wherein a content of an abrasive grain based on a total mass of the polishing composition is less than 0.5% by mass:
[9] The polishing composition according to any of [1] to [8], wherein the object to be polished includes a material having a silicon-silicon bond:
[10] The polishing composition according to [9], wherein the material having a silicon-silicon bond is amorphous silicon:
[11] The polishing composition according to [9] or [10], wherein the object to be polished further includes a material having a silicon-nitrogen bond:
[12] A polishing method containing polishing a material having a silicon-silicon bond, in which the material is embedded on a substrate having a depressed portion so as to cover the depressed portion, with the polishing composition according to any of [1] to [11].

### EXAMPLES

The present disclosure is described in further detail with reference to the following Examples and Comparative Examples. However, the technical scope of the present disclosure is not limited to only the following Examples. Unless particularly noted, “%” and “part(s)” respectively mean “% by mass” and “part(s) by mass”.

### <Weight Average Molecular Weight of (A) Component>

The weight average molecular weight of the (A) component was measured by gel permeation chromatography (GPC) with polyethylene glycol as a standard substance. Detailed conditions are as described below:
GPC apparatus: manufactured by Shimadzu Corporation
Model: Prominence+ELSD detector (ELSD-LTII)
Column: VP-ODS (manufactured by Shimadzu Corporation)
Mobile phase A: MeOH
Mobile phase B: aqueous 1% acetic acid solution
Flow rate: 1 mL/min
Detector: ELSD temp. 40° C., Gain 8, N₂ GAS 350 kPa
Oven temperature: 40° C.
Amount of injection: 40 μl.

### <pH of Polishing Composition>

The pH of the polishing composition was measured as a value at 25° C. with a pH meter (Model number: LAQUA (registered trademark) manufactured by Horiba Ltd.).

### <Electrical Conductivity of Polishing Composition>

The electrical conductivity (EC) of the polishing composition was measured with a desktop-type electrical conductivity meter (Model number: DS-71 manufactured by Horiba Ltd.).

### <Average Primary Particle Size of Abrasive Grain>

The average primary particle size of the abrasive grain was calculated from the specific surface area of a silica particle according to a BET method, as measured with “Flow Sorb II 2300” manufactured by Micromeritics Instrument Corporation, and the density of the abrasive grain.

### <Average Secondary Particle Size of Abrasive Grain>

The average secondary particle size of the abrasive grain was measured as the volume average particle size with a laser light scattering measurement apparatus Zetasizer Ultra (manufactured by Malvern Panalytical Ltd.).

### <Zeta Potential of Abrasive Grain>

The zeta potential of the abrasive grain in the polishing composition was measured with a zeta potential measurement apparatus (equipment name “ELS-Z2”) manufactured by Otsuka Electronics Co., Ltd.

### <Components of Polishing Composition>

The details of the abrasive grain and the (A) component used for preparation of the polishing composition are as follows:
Abrasive grain: colloidal silica, average primary particle size 35 nm, average secondary particle size 70 nm
HEC: hydroxyethylcellulose, Mw: 90,000
CMC: carboxymethylcellulose, Mw: 120,000
MC: methylcellulose, Mw: 50,000
PVP: polyvinylpyrrolidone, Mw: 45,000
PVA: polyvinyl alcohol, Mw: 10,000
PA: polyacrylic acid, Mw: 200,000.

### <Object to be Polished>

A silicon wafer (a-Si substrate, diameter 300 mm) where an amorphous silicon film having a thickness of 2000 Å was formed by CVD on the wafer and a silicon wafer (SiN substrate, diameter 300 mm) where a SiN film having a thickness of 2500 Å was formed on the wafer were each prepared as an object to be polished (object to be polished for polishing removal rate evaluation) used for evaluation of the polishing removal rate, an object to be polished (object to be polished for etching rate evaluation) used for evaluation of the etching rate, and an object to be polished (object to be polished for film thickness evaluation of coating film) used for evaluation of the film thickness of the coating film.

An object to be polished used for evaluation of the step elimination ability (object to be polished for step elimination ability evaluation), used here, was a silicon wafer where an amorphous silicon film having a thickness of 3000 Å and an initial step of 800 Å was formed on a surface of the wafer.

### Example 1

300 g of ultrapure water was added to 0.05 g of hydroxyethylcellulose (PVP) as the (A) component and the resultant was stirred. Next, 0.5 g of N-(2-aminoethyl)piperazine (AEP) as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 1.

### Example 2

Polishing composition 2 was prepared in the same manner as in Example 1 except that 0.05 g of carboxymethylcellulose was added instead of hydroxyethylcellulose.

### Example 3

Polishing composition 3 was prepared in the same manner as in Example 1 except that 0.05 g of methylcellulose was added instead of hydroxyethylcellulose.

### Example 4

300 g of ultrapure water was added to 0.5 g of polyvinylpyrrolidone as the (A) component and the resultant was stirred. Next, 1.0 g of N-(2-aminoethyl)piperazine (AEP) as the (B) component and 300 g of ultrapure water were added. Furthermore, nitric acid as the pH adjusting agent was added in an amount so that the final pH of the polishing composition was 10.5, and ultrapure water was added so that the total mass of the polishing composition was 1 kg, thereby preparing polishing composition 4.

### Example 5

Polishing composition 5 was prepared in the same manner as in Example 4 except that 20.0 g of piperazine was added instead of N-(2-aminoethyl)piperazine (AEP) and nitric acid was added in an amount so that the final pH of the polishing composition was 9.0.

### Example 6

300 g of ultrapure water was added to 0.5 g of polyvinylpyrrolidone as the (A) component and the resultant was stirred. Next, 20.0 g of piperazine as the (B) component and 300 g of ultrapure water were added. Colloidal silica as the abrasive grain was further added in an amount so that the final concentration was 0.1% by mass, nitric acid as the pH adjusting agent was added in an amount so that the final pH of the polishing composition was 9.5, and ultrapure water was added so that the total mass of the polishing composition was 1 kg, thereby preparing polishing composition 6.

### Example 7

300 g of ultrapure water was added to 0.5 g of polyvinylpyrrolidone as the (A) component and the resultant was stirred. Next, 5.0 g of imidazole as the (B) component and 300 g of ultrapure water were added. Colloidal silica as the abrasive grain was further added in an amount so that the final concentration was 0.1% by mass, nitric acid as the pH adjusting agent was added in an amount so that the final pH of the polishing composition was 10.5, and ultrapure water was added so that the total mass of the polishing composition was 1 kg, thereby preparing polishing composition 7.

### Comparative Example 1

300 g of ultrapure water was added to 0.05 g of hydroxyethylcellulose as the (A) component and the resultant was stirred. Next, 0.05 g of N-(2-aminoethyl)piperazine (AEP) as the (B) component and 300 g of ultrapure water were added. Furthermore, ammonia as the pH adjusting agent was added in an amount so that the final pH of the polishing composition was 10.5, and ultrapure water was added so that the total mass of the polishing composition was 1 kg, thereby preparing polishing composition comparison 1.

### Comparative Example 2

Polishing composition comparison 2 was prepared in the same manner as in Comparative Example 1 except that 0.05 g of carboxymethylcellulose was added instead of hydroxyethylcellulose.

### Comparative Example 3

Polishing composition comparison 3 was prepared in the same manner as in Comparative Example 1 except that 0.05 g of methylcellulose was added instead of hydroxyethylcellulose.

### Comparative Example 4

300 g of ultrapure water was added to 0.5 g of polyvinylpyrrolidone as the (A) component and the resultant was stirred. Next, 0.1 g of N-(2-aminoethyl)piperazine (AEP) as the (B) component and 300 g of ultrapure water were added. Furthermore, ammonia as the pH adjusting agent was added in an amount so that the final pH of the polishing composition was 10.5, and ultrapure water was added so that the total mass of the polishing composition was 1 kg, thereby preparing polishing composition comparison 4.

### Comparative Example 5

300 g of ultrapure water was added to 0.8 g of polyvinyl alcohol (PVA) as the (A) component and 0.2 g of polyacrylic acid (PA), and the resultant was stirred. Next, 1.0 g of N-(2-aminoethyl)piperazine (AEP) as the (B) component and 300 g of ultrapure water were added. Furthermore, nitric acid as the pH adjusting agent was added in an amount so that the final pH of the polishing composition was 10.0, and ultrapure water was added so that the total mass of the polishing composition was 1 kg, thereby preparing polishing composition comparison 5.

### [Etching Rate (Etching Test in Condition A)]

A coupon wafer obtained by cutting the object to be polished (amorphous silicon) for the etching rate evaluation, prepared above, to a size of 60 mm×60 mm, was dipped in 500 ml of the polishing composition being stirred. Dipping conditions are as described below:
Dipping time: 120 minutes
Dipping temperature: 40° C.
Rotational speed of stirrer: 300 rpm

The etching rate was calculated by determining the thicknesses of the amorphous silicon film before and after dipping with an optical film thickness measurement instrument (RE-3500: manufactured by SCREEN Holdings Co., Ltd.), and dividing [(Thickness before dipping)−(Thickness after dipping)] by the dipping time.

### [Polishing Conditions]

The polishing compositions of Examples and Comparative Examples were used to polish an object to be polished for polishing removal rate evaluation in the following polishing conditions:
Polishing apparatus: F-REX 300E manufactured by Ebara Corporation
Polishing pad: IK4250H (shore D hardness: 60) manufactured by Du Pont
Polishing time: 20 seconds
Pressure of polishing table pressure: 2.5 psi (17.2 kPa)
Number of rotations of polishing table: 60 rpm
Number of rotations of carrier: 63 rpm
Supply rate of polishing composition: 200 ml/min

### [Measurement of Polishing Removal Rate]

The polishing removal rate (polishing rate) of the object to be polished was calculated by the following expression.

$$[ Expression 1 ]$$

$$Polishing removal rate [ Å / min ] = ( Film thickness [ Å ] before polishing - Film thickness [ Å ] after polishing ) / Polishing time [ min ]$$

The thicknesses before and after polishing of the object to be polished were determined with a light interference type film thickness measurement apparatus (Model number: A-SET F5X manufactured by KLA-Tencor), and the difference therebetween was divided by the polishing time to calculate the polishing removal rate.

### [Thickness of Coating Film]

The film thickness of the coating film on the amorphous silicon film was measured as follows. A test piece prepared here is a coupon wafer obtained by cutting an object to be polished for film thickness measurement of the coating film, to a size of 60 mm×60 mm, and polished with the polishing compositions obtained by Examples and Comparative Examples in the following conditions:
Polishing apparatus: desktop polishing machine EJ-380 IN manufactured by ENGIS JAPAN Corporation
Polishing pad: IK4250H (shore D hardness: 60) manufactured by Du Pont
Polishing pressure: 2.25 psi (15.51 kPa)
Number of rotations of polishing table: 90 rpm
Number of rotations of head: 60 rpm
Flow rate of polishing composition: 15 mL/min
Polishing time: 60 seconds.

After polishing was performed in the above polishing conditions, a surface of the object to be polished was dried with an air gun. Thereafter, the film thickness of the coating film was measured with a film thickness measurement machine (RE-3500: manufactured by SCREEN Holdings Co., Ltd.). Here, one where the value of GOF (Goodness of Fit) was 0.9 or more was adopted as a measurement value.

### [Step Elimination Ability (Step Elimination Efficiency)]

The above-prepared object to be polished for step elimination ability evaluation was cut to a size of 60 mm×60 mm, and a surface thereof was polished by only 1000 Å in the following polishing conditions. The value of the step elimination efficiency was obtained as the value by dividing the amount of step elimination, as determined by subtracting the step after polishing from the initial step, (initial step-step after polishing), by the amount of polishing (1000 Å), as expressed in terms of percentage (see the following expression). The step was measured with an atomic force microscope (AFM, manufactured by Bruker, Dimension ICON). The step elimination efficiency is more preferably closer to a numerical value of 100%:
Polishing apparatus: desktop polishing machine EJ-380 IN manufactured by ENGIS JAPAN Corporation
Polishing pad: IK4250H (shore D hardness: 60) manufactured by Du Pont
Pressure of polishing table: 2.5 psi (17.2 kPa)
Number of rotations of polishing table: 90 rpm
Supply rate of polishing composition: 20 ml/min.

$$[ Expression 2 ]$$

$$Step elimination efficiency ( \% ) = ( A mount of step elimination / Amount of polishing ) \times 100$$

The constitutions of the polishing compositions of Examples and Comparative Examples are shown in Table 1 below, and the results of each evaluation described above are shown in Table 2.

TABLE 1

| | | Abrasive grain | | | | | |
|---|---|---|---|---|---|---|---|
| | | Average | | | | | |
| | | secondary | | | | | |
| | | particle | Zeta | | (A) Component | | |
| | Composition | size | potential | Concentration | | | Concentration |
| | No. | (nm) | (mV) | (% by mass) | Type | Mw | (% by mass) |
| Example 1 | 1 | — | — | — | HEC | 90,000 | 0.005 |
| Example 2 | 2 | — | — | — | CMC | 120,000 | 0.005 |
| Example 3 | 3 | — | — | — | MC | 50,000 | 0.005 |
| Example 4 | 4 | — | — | — | PVP | 45,000 | 0.05 |
| Example 5 | 5 | — | — | — | PVP | 45,000 | 0.05 |
| Example 6 | 6 | 70 | −40 | 0.1 | PVP | 45,000 | 0.05 |
| Example 7 | 7 | 70 | −40 | 0.1 | PVP | 45,000 | 0.05 |
| Comparative | Comparison | — | — | — | HEC | 90,000 | 0.005 |
| Example 1 | 1 | | | | | | |
| Comparative | Comparison | — | — | — | CMC | 120,000 | 0.005 |
| Example 2 | 2 | | | | | | |
| Comparative | Comparison | — | — | — | MC | 50,000 | 0.005 |
| Example 3 | 3 | | | | | | |
| Comparative | Comparison | — | — | — | PVP | 45,000 | 0.05 |
| Example 4 | 4 | | | | | | |
| Comparative | Comparison | — | — | — | PVA | 10,000 | 0.08 |
| Example 5 | 5 | | | | PA | 200,000 | 0.02 |

| | | | Content mass | | | |
|---|---|---|---|---|---|---|
| | (B) Component | | ratio of (B) | pH | | |
| | | Concentration | Component/(A) | adjusting | | EC |
| | Type | (% by mass) | Component | agent | pH | (mS/cm) |
| Example 1 | AEP | 0.05 | 10 | HNO₃ | 10.5 | 1.0 |
| Example 2 | AEP | 0.05 | 10 | HNO₃ | 10.5 | 1.2 |
| Example 3 | AEP | 0.05 | 10 | HNO₃ | 10.5 | 1.0 |
| Example 4 | AEP | 0.1 | 2 | HNO₃ | 10.5 | 1.0 |
| Example 5 | Piperazine | 2 | 40 | HNO₃ | 9.0 | 7.0 |
| Example 6 | Piperazine | 2 | 40 | HNO₃ | 9.5 | 7.0 |
| Example 7 | Imidazole | 0.5 | 10 | HNO₃ | 10.5 | 2.5 |
| Comparative | AEP | 0.005 | 1 | NH₃ | 10.5 | 1.0 |
| Example 1 | | | | | | |
| Comparative | AEP | 0.005 | 1 | NH₃ | 10.5 | 1.2 |
| Example 2 | | | | | | |
| Comparative | AEP | 0.005 | 1 | NH₃ | 10.5 | 1.0 |
| Example 3 | | | | | | |
| Comparative | AEP | 0.01 | 0.2 | NH₃ | 10.5 | 0.5 |
| Example 4 | | | | | | |
| Comparative | AEP | 0.1 | 1 | HNO₃ | 10.0 | 1.0 |
| Example 5 | | | | | | |

TABLE 2

| | | Film | | Polishing | | |
|---|---|---|---|---|---|---|
| | | thickness | | removal | | Step |
| | | of coating | Etching | rate | | elimination |
| | Composition | film | rate | (Å/min) | | efficiency |
| | No. | (Å) | (Å/min) | a-Si | SiN | (%) |
| Example 1 | 1 | 23 | 1.9 | 1645 | 0 | 42 |
| Example 2 | 2 | 22 | 2.1 | 2076 | 0 | 41 |
| Example 3 | 3 | 25 | 1.9 | 1989 | 0 | 43 |
| Example 4 | 4 | 20 | 1.4 | 1812 | 0 | 39 |
| Example 5 | 5 | 26 | 1.1 | 1856 | 0 | 43 |
| Example 6 | 6 | 26 | 1.1 | 1992 | 8 | 44 |
| Example 7 | 7 | 24 | 0.9 | 1890 | 7 | 43 |
| Comparative | Comparison | 18 | 0.2 | 1278 | 0 | 33 |
| Example 1 | 1 | | | | | |
| Comparative | Comparison | 14 | 0.4 | 1233 | 0 | 30 |
| Example 2 | 2 | | | | | |
| Comparative | Comparison | 11 | 0.3 | 1355 | 0 | 29 |
| Example 3 | 3 | | | | | |
| Comparative | Comparison | 16 | 0.7 | 1530 | 6 | 32 |
| Example 4 | 4 | | | | | |
| Comparative | Comparison | 25 | 0.2 | 5 | 0 | 31 |
| Example 5 | 5 | | | | | |

As clear from Table 2 above, it has been found that the polishing compositions of Examples can allow the polishing removal rate of a material having a silicon-silicon bond to be enhanced and are also excellent in step elimination ability on an object to be polished, as compared with the polishing compositions of Comparative Examples.

Here, the polishing composition of Comparative Example 5 includes much PVA strongly interacting with amorphous silicon, and thus it is considered that a coating film formed, although is thicker, is hardly released, resulting in reductions in etching rate and polishing removal rate.

The present application is based on Japanese Patent Application No. 2025-044830 filed on Mar. 19, 2025, the disclosure of which is herein incorporated by reference in its entirety.

1. A polishing composition comprising
(A) a water-soluble polymer, and
(B) a polishing accelerator, wherein
a content mass ratio of the (B) component to the (A) component ((B) component/(A) component) is more than 1,
a dry film thickness measured by ellipsometry, of a coating film containing the (A) component and the (B) component, in which the coating film is formed after polishing of an object to be polished with the polishing composition comprising the (A) component and the (B) component, is 20 Å or more, and
an etching rate of the object to be polished, in the case of an etching test performed with the polishing composition comprising the (A) component and the (B) component in Condition A, is 0.5 Å/min or more.

2. The polishing composition according to claim 1, wherein the (A) component is at least one selected from the group consisting of polyvinylpyrrolidone, hydroxymethylcellulose, hydroxyethylcellulose, methylcellulose, and carboxymethylcellulose.

3. The polishing composition according to claim 1, wherein the (B) component is an amine compound having 3 or more carbon atoms.

4. The polishing composition according to claim 3, wherein the (B) component is at least one selected from the group consisting of piperazine, 1-(2-aminoethyl)piperazine, 1,4-bis(3-aminopropyl)piperazine, and imidazole.

5. The polishing composition according to claim 1, wherein the content mass ratio of the (B) component to the (A) component ((B) component/(A) component) is more than 10 and 50 or less.

6. The polishing composition according to claim 1, further comprising a dispersing medium.

7. The polishing composition according to claim 1, wherein a pH is 8 or more and 12 or less.

8. The polishing composition according to claim 1, wherein a content of an abrasive grain based on a total mass of the polishing composition is less than 0.5% by mass.

9. The polishing composition according to claim 1, wherein the object to be polished includes a material having a silicon-silicon bond.

10. The polishing composition according to claim 9, wherein the material having a silicon-silicon bond is amorphous silicon.

11. The polishing composition according to claim 9, wherein the object to be polished further includes a material having a silicon-nitrogen bond.

12. A polishing method comprising polishing a material having a silicon-silicon bond, in which the material is embedded on a substrate having a depressed portion so as to cover the depressed portion, with the polishing composition according to claim 1.
